(19) United States
(12) Patent Application Publication
(10) Pub. No.: US 2015/0126029 A1
(43) Pub. Date: May 7, 2015

(54) DRY FILM PHOTORESIST, MANUFACTURING METHOD OF DRY FILM PHOTORESIST, METAL PATTERN FORMING METHOD AND ELECTRONIC COMPONENT

(71) Applicant: Sony Corporation, Tokyo (JP)

(72) Inventors: Hideki Kimura, Kanagawa (JP); Nozomu Hoshi, Miyagi (JP); Yoshihiko Takahashi, Miyagi (JP); Kenji Katsumata, Miyagi (JP)

(21) Appl. No.: 14/498,149

(22) Filed: Sep. 26, 2014

(30) Foreign Application Priority Data
Nov. 5, 2013 (JP) 2013-229034

(51) Int. Cl. H01L 21/3213; H01L 21/3205; G03F 7/038; H01L 21/027

(52) U.S. Cl. CPC H01L 21/32139; H01L 21/0272; H01L 21/32051; G03F 7/038
USPC 438/670; 438/763; 430/280.1

(57) ABSTRACT

There is provided a dry film photoresist including a substrate layer constituted by a certain substrate, a resist layer disposed over the substrate layer, the resist layer including a plurality of layers, and a protective film layer disposed over the resist layer, the protective film layer protecting the resist layer. A photosensitive layer is positioned on a side of the substrate layer of the resist layer, the photosensitive layer having a dissolution rate to a certain developer that decreases by being exposed to light, and a non-photosensitive layer is positioned on a side of the protective film layer of the resist layer, the non-photosensitive layer being soluble to the developer. A dissolution rate of the non-photosensitive layer to the developer is higher than a dissolution rate of an unexposed portion in the photosensitive layer to the developer.

### CROSS REFERENCE TO RELATED APPLICATIONS

This application claims the benefit of Japanese Priority Patent Application JP 2013-229034 filed Nov. 5, 2013, the entire contents of which are incorporated herein by reference.

### BACKGROUND

The present disclosure relates to a dry film photoresist, a manufacturing method of the dry film photoresist, a metal pattern forming method and an electronic component.

The dry film photoresist includes a supporting substrate layer, a photosensitive layer and a protective layer sequentially laminated to each other, is supplied in the form of a rolled shape, and is often used in the manufacture of printed circuit boards or the like. When the printed circuit boards are manufactured, the dry film photoresist, from which the protective layer has been removed, is bonded on a circuit board, and irradiated with ultraviolet light having a desired pattern, thereby to cure the photosensitive layer in the irradiated position. Thereafter, the supporting substrate layer is removed, and then the photosensitive layer in a non-irradiated position, which is not cured by the irradiation of ultraviolet light, is removed. Accordingly, a resist having a desired pattern is formed on the circuit board. Such a patterned resist is used as a mask for etching or plating.

A manufacturing method of a printed circuit board using such a dry film photoresist falls roughly into three categories of a subtractive method, a semi-additive method and a full additive method. However, since these methods involve plating as a metal film forming method, the metal species suitable for plating are limited. Thus, the metal species may not be freely selected.

On the other hand, when a vapor deposition method is used as a metal film forming method, a metal film may be formed with any metal as long as the metal is allowed to be vapor deposited. However, when a metal film is formed on a resist having a general cross-sectional forward tapered shape and then the photoresist is removed for lift-off, a so-called “burr” is generated on the edge of the metal film pattern, causing failures such as film peeling.

To address this concern, JP S63-29552A discloses a method of vapor-depositing a metal film on a negative resist having an opening with a photoresist cross-sectional shape of reverse taper utilizing light diffusion within a film photoresist, and removing the photoresist for lift-off to obtain a metal film pattern. By using such a method, in a vapor deposited film, the scattering of the incident angle of metal particles decreases, thereby enabling lift-off.

Also, JP 2003-282405A discloses a technique of repeating a process of photoresist formation, exposure, and development twice in this order so that an eaves shape with an optional size may be obtained. By using such a method, even when a sputtering method is used, lift-off is enabled without the occurrence of a “burr”.

On the other hand, JP 2004-46007A discloses a technique of using a liquid resist to provide an eaves-shaped resist for performing lift-off.

Furthermore, other pattern forming techniques using the dry film photoresist include techniques disclosed in JP 2007-532945A, JP 2007-52351A and JP H11-260255A. The technique disclosed in JP 2007-532945A is a technique of using a laminate including two types of monolayer dry film photoresists having a different solubility from each other to provide an eaves-shaped resist for performing lift-off. The technique disclosed in JP 2007-52351A is a technique regarding a laminated dry resist in which a photosensitive layer is arranged in an upper layer while a non-photosensitive layer is arranged in a lower layer. The technique disclosed in JP H11-260255A is a technique regarding a laminated dry resist in which a non-photosensitive layer is arranged in an upper layer while a photosensitive layer is arranged in a lower layer.

### SUMMARY

However, in the technique disclosed in JP 563-29552A described above, since a decrease in a photoresist light reaction amount due to the light scattering within the photoresist is utilized when forming the reverse-tapered cross-sectional shape, the overhang amount by the reverse taper is limited. For this reason, the incident angle of metal particles becomes larger in a sputtering method, resulting in the attachment of metal particles on the side surface of a photoresist tapered wall. Accordingly, a metal film is peeled off at lift-off, or the flatness of a metal film deteriorates.

Also, in the technique disclosed in JP 2003-282405A described above, since a photolithography pattern forming process comes to be repeated twice, the number of processes increases, resulting in increased cost.

Furthermore, the technique disclosed in JP 2004-46007A described above uses a liquid resist. Accordingly, when such a technique is applied to a large step-shaped product, a photoresist comes to be convexly coated in a non-uniform film thickness. As a result, the resist patterning accuracy deteriorates, or the etching processing accuracy deteriorates due to an insufficient resist film thickness.

Also, in the technique disclosed in JP 2007-532945A described above, since exposure and development are performed after each of the monolayer dry film resists is bonded on the substrate, the number of processes increases, resulting in increased cost.

Furthermore, in the technique disclosed in JP 2007-52351A, the non-photosensitive layer is disposed in the lower layer of the photosensitive layer for the purpose of improving the peeling properties of a resist. In such a laminating order, an eaves shape is difficult to form. As a result, when such a technique is applied to lift-off, a “burr” occurs, causing film peeling or the like.

Also, in the technique disclosed in JP H11-260255A described above, the photosensitive layer is disposed in the lower layer to the non-photosensitive layer for the purpose of ensuring adhesion in bonding the dry resist on the substrate. Even in such a laminating order, an appropriate eaves shape is difficult to form. As a result, when such a technique is applied to lift-off, a “burr” occurs, causing film peeling or the like.

Therefore, in view of the above-described circumstances, the present disclosure proposes a dry film photoresist, a manufacturing method of the dry film photoresist, a metal pattern forming method and an electronic component, in which a metal film pattern is enabled to be accurately formed without inviting a decrease in productivity independently from a metal film forming method.

According to an embodiment of the present disclosure, there is provided a dry film photoresist including a substrate layer constituted by a certain substrate, a resist layer disposed over the substrate layer, the resist layer including a plurality of layers, and a protective film layer disposed over the resist layer, the protective film layer protecting the resist layer. A photosensitive layer is positioned on a side of the substrate layer of the resist layer, the photosensitive layer having a dissolution rate to a certain developer that decreases by being exposed to light, and a non-photosensitive layer is positioned on a side of the protective film layer of the resist layer, the non-photosensitive layer being soluble to the developer. A dissolution rate of the non-photosensitive layer to the developer is higher than a dissolution rate of an unexposed portion in the photosensitive layer to the developer.

According to another embodiment of the present disclosure, there is provided a manufacturing method of a dry film photoresist, the manufacturing method including forming a resist layer including a plurality of layers on a certain substrate, and forming a protective film layer that protects the resist layer on the resist layer. In forming the resist layer, a photosensitive layer is formed on a side of the substrate, the photosensitive layer having a dissolution rate to a certain developer that decreases by being exposed to light, a non-photosensitive layer is formed on a side of the protective film layer, the non-photosensitive layer being soluble to the developer, and a dissolution rate of the non-photosensitive layer to the developer is adjusted to be higher than a dissolution rate of an unexposed portion in the photosensitive layer to the developer.

According to another embodiment of the present disclosure, there is provided a metal pattern forming method including arranging a dry film photoresist on a surface of a processing target material, irradiating the dry film photoresist with exposing light, and then performing development with a certain developer, so that the dry film photoresist has a cross section of an eaves-like shape, forming a metal film over the dry film photoresist having the processed cross section, using a physical vapor deposition method, and removing the dry film photoresist. The dry film photoresist arranged on the surface of the processing target material has a resist layer including a plurality of layers. A non-photosensitive layer is positioned on a side of the processing target material of the resist layer, the non-photosensitive layer being soluble to the developer, and a photosensitive layer is positioned on a side of the metal film of the resist layer, the photosensitive layer having a dissolution rate to the certain developer that decreases by being exposed to light. A dissolution rate of the non-photosensitive layer to the developer is higher than a dissolution rate of an unexposed portion in the photosensitive layer to the developer.

Also, according to the present disclosure, an electronic component manufactured by the above-described metal pattern forming method is provided.

According to the present disclosure, in a dry film photoresist, the dissolution rate of a non-photosensitive layer to a developer is higher than the dissolution rate of an unexposed portion in a photosensitive layer to a developer. Accordingly, during development processing, the non-photosensitive layer is dissolved faster than the unexposed portion in the photosensitive layer. As a result, by using the dry film photoresist according to an embodiment of the present disclosure, a resist layer having a cross-sectional eaves shape is formed.

As described above, according to the present disclosure, a metal film pattern is enabled to be accurately formed by lift-off without inviting a decrease in productivity independently from a metal film forming method.

Here, the above effects are not necessarily limiting. In addition to the above-described effects, or in place of the above-described effects, any one of the effects indicated in this specification or other effects that can be understood from this specification may be exerted.

### BRIEF DESCRIPTION OF THE DRAWINGS

FIG. 1 is an illustrative diagram schematically showing a layer structure of a dry film photoresist according to the first embodiment of the present disclosure;

FIG. 2 is a flow diagram showing an example of the flow of the manufacturing method of the dry film photoresist according to the first embodiment;

FIG. 3 is an illustrative diagram schematically showing a flow of a metal pattern forming method utilizing the dry film photoresist according to the first embodiment;

FIG. 4 is an exploded perspective view schematically showing a thermal assist magnetic recording unit;

FIG. 5 is a flow diagram showing an example of the flow of the manufacturing method of the magnetic head according to the first embodiment;

FIG. 6 is an illustrative diagram for explaining a manufacturing method of a magnetic head according to the first embodiment; and

FIG. 7 is a cross-sectional enlarged view showing a specific example of a cross-sectional eaves shape of a resist layer.

### DETAILED DESCRIPTION OF THE EMBODIMENT(S)

Hereinafter, preferred embodiments of the present disclosure will be described in detail with reference to the appended drawings. Note that, in this specification and the appended drawings, structural elements that have substantially the same function and structure are denoted with the same reference numerals, and repeated explanation of these structural elements is omitted.

Note that description will be provided in the following order.
1. First embodiment
1.1 Regarding dry film photoresist
1.2 Regarding manufacturing method of dry film photoresist
1.3 Regarding metal pattern forming method
1.4 Regarding manufacturing method of magnetic head
2. Example

### First Embodiment

### <Regarding Dry Film Photoresist>

### [Layer Structure of Dry Film Photoresist]

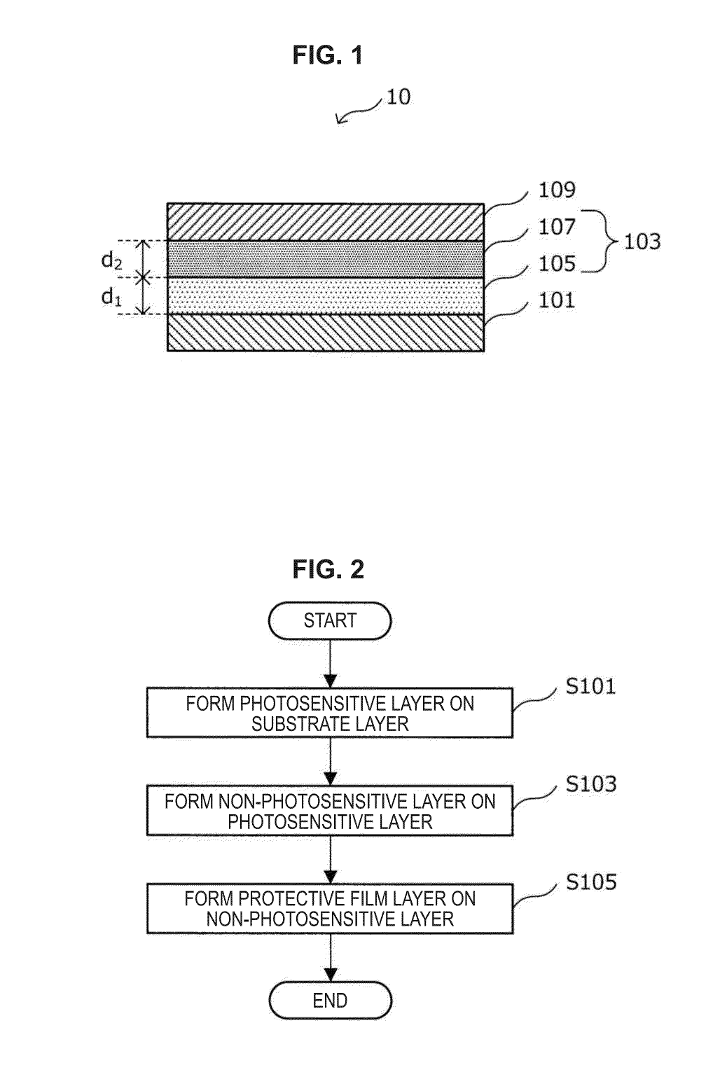

First, by referring to FIG. 1, a layer structure of a dry film photoresist 10 according to a first embodiment of the present disclosure will be described in detail. FIG. 1 is an illustrative diagram schematically showing the layer structure of the dry film photoresist according to the present embodiment.

The dry film photoresist 10 according to the present embodiment includes, as shown in FIG. 1, a substrate layer 101, a resist layer 103 and a protective film layer 109. Such a dry film photoresist 10 is used when forming a metal film by a physical vapor deposition method.

The substrate layer 101 is a layer that functions as a substrate to support the resist layer 103 and the protective film layer 109 described later. The substrate layer 101 is formed with a resin that has appropriate flexibility and that is transparent to the light used in the exposure processing of a photolithography method. Such a resin is not particularly limited, and publicly known resins such as polyester and polyethylene terephthalate may be used. Also, the thickness of the substrate layer 101 is not particularly limited, and may be approximately 10 to 30 μm.

The resist layer 103 is disposed on the substrate layer 101. The resist layer 103 is a layer containing a composition in which physical properties such as dissolution rates are changed due to irradiated light. The resist layer 103 is constituted by a plurality of layers, and includes, as shown in FIG. 1, at least a photosensitive layer 105 and a non-photosensitive layer 107. The resist layer 103 will be described in detail below.

On the resist layer 103, the protective film layer 109 that protects such a resist layer 103 is disposed. The protective film layer 109 is formed with a resin that has appropriate flexibility. Such a resin is not particularly limited, and publicly known resins such as polyethylene may be used. Also, the thickness of the protective film layer 109 is not particularly limited, and may be approximately 20 to 50 μm.

### Regarding Structure of Resist Layer 103

As previously described, the resist layer 103 of the dry film photoresist 10 according to the present embodiment includes at least the photosensitive layer 105 and the non-photosensitive layer 107.

The photosensitive layer 105 is a layer disposed on a side of the substrate layer 101 in the resist layer 103, and is a layer formed with a photosensitive compound in which the dissolution rate to a certain developer decreases by being irradiated with certain light for exposure. Also, the non-photosensitive layer 107 is a layer disposed on a side of the protective film layer 109 in the resist layer 103, and is a layer that is not photosensitized even by the light irradiated to the photosensitive layer 105 and is formed with a non-photosensitive compound being soluble to a developer.

Also, in the resist layer 103 according to the present embodiment, the dissolution rate of the non-photosensitive layer 107 to a developer is higher than the dissolution rate of an unexposed portion in the photosensitive layer 105 to a developer. As described later, when such a dry film photoresist is used to perform photolithography processing to a processing target material, the order of the layer structure shown in FIG. 1 is reversed such that the non-photosensitive layer 107 is positioned on a side of a surface of a processing target material while the photosensitive layer 105 is positioned on a side of an upper surface of the non-photosensitive layer 107. Here, since the dissolution rate of the non-photosensitive layer 107 to a developer is as described above, the dissolution of the non-photosensitive layer 107 positioned on a side of a processing target material on which a metal pattern is formed, to a developer, proceeds faster than the dissolution of the unexposed portion of the photosensitive layer 105 positioned closer to the surface side. As a result, in the cross section of the resist layer 103, there is formed a shape (a so-called eaves shape) in which the edge of the dissolved photosensitive layer 105 protrudes beyond the edge of the non-photosensitive layer 107 positioned in the lower layer. By the formation of such an eaves shape, when forming an optional metal film by a publicly known physical vapor deposition method such as a vapor deposition method or a sputtering method, a resist pattern may be removed to lift off the metal film so that a metal pattern without a “burr” is formed.

When a metal film is formed on the cross-sectional eaves shaped resist layer 103 and the exposed surface of the processing target material, discontinuity occurs between the metal film layer formed on the photosensitive layer 105 and the metal film layer formed on the surface of the processing target material, thereby enabling the formation of a metal pattern without a “burr”. Therefore, in order to allow such discontinuity to occur, the thickness of the non-photosensitive layer 107 (a thickness d₂ in FIG. 1) may be approximately at least the same level as the thickness of the metal film to be formed. Here, in order to more surely allow the above-described discontinuity to occur, for example, the thickness d₂ of the non-photosensitive layer 107 preferably satisfies the relationship of formula 101 below.

Thickness of non-photosensitive layer 107≧Thickness of metal film to be formed×1.2 (formula 101)

Also, the thickness (a thickness d₁ in FIG. 1) of the photosensitive layer 105 is preferably not less than twice the thickness of a metal film to be formed, in order to inhibit an occurrence of deformation of the film pattern of the photosensitive layer 105 due to the film stress attributable to a metal film to be formed and the thermal radiation associated with a physical vapor deposition method.

The minimum developing time taken for developing the photosensitive layer 105 to form a desired pattern is determined according to the thickness d₁ of the photosensitive layer 105. Here, when in the photosensitive layer 105 having a thickness of d₁ [μm], the minimum developing time taken for forming a pattern is tₘᵢₙ [second], a minimum dissolution rate v_{1 min} of the photosensitive layer 105 is d₁/tₘᵢₙ [μm/second]. However, in order to more surely perform development processing of the photosensitive layer 105, a total developing time tₜₒₜₐₗ is usually set at approximately 1.5 times the minimum developing time tₘᵢₙ in many cases.

On the other hand, in the non-photosensitive layer 107, the non-photosensitive compound corresponding to the thickness d₂ and an eaves component of the non-photosensitive layer 107 preferably dissolves with a margin of 50%, in a surplus developing time expressed as (total developing time tₜₒₜₐₗ—minimum developing time tₘᵢₙ). Therefore, the dissolution rate (etching rate) that may be necessary for the non-photosensitive layer 107 is estimated based on formula 102 below. Formula 102 below indicates, as evident from the contents thereof, that a lower limit of a dissolution rate v₂ of the non-photosensitive layer 107 is defined by the dissolution rate at which the thickness d₂ of the non-photosensitive layer 107 dissolves with a margin of 50%.

v₂≧d₂/((tₜₒₜₐₗ−tₘᵢₙ)/1.5) (formula 102)

Therefore, when the thickness d₂ of the non-photosensitive layer 107 is 30 μm and the total developing time tₜₒₜₐₗ defined from the above-described minimum developing time tₘᵢₙ is 40 seconds, the lower limit of the dissolution rate v₂ of the non-photosensitive layer 107 may be estimated as being 3.46 [μm/second] from the above-described formula 102.

Such a photosensitive layer 105 may be formed as a resin layer containing at least a binder resin, a polymerizable monomer and a photopolymerization initiator.

An example of the binder resin to be used may be a resin selected from the group consisting of an acrylic-based resin, a methacrylic-based resin and an epoxy-based resin, or a copolymer of the resin. Also, the molecular weight of such a resin or copolymer is preferably 5000 to 200000.

An example of the polymerizable monomer to be used may be a monomer selected from the group consisting of an acrylic-based monomer, a methacrylic-based monomer, a styrene-based monomer and an ethylene-based unsaturated compound.

Also, the photopolymerization initiator is not particularly limited, and publicly known photopolymerization initiators such as dimethyl methacrylate and 4-dimethyl ethyl aminobenzoate may be used.

Also, the photosensitive layer 105 may contain a component other than the binder resin, polymerizable monomer and photopolymerization initiator as necessary.

A specific example of the photosensitive layer 105 containing the components described above may include, but not limited to, a layer as listed below. Here, in Table 1 below, “EO-modified” means having an ethylene oxide group (—CH₂—CH₂—O—).

TABLE 1
Example of photosensitive layer 105

| | | Compo- |
|---|---|---|
| | | sition |
| Component | | (mass %) |
| Binder | Methyl ethyl ketone solution of copolymer | 85 |
| resin | of methyl methacrylate:methacrylic | |
| | acid:butyl acrylate = 60:30:10 | |
| Polymerizable | EO-modified trimethyl propane triacrylate | 4.5 |
| monomer | polypropylene glycol | |
| | 2,4-diethylthioxanthone | 9.0 |
| Photopoly- | Dimethyl methacrylate | 0.5 |
| merizable | 4-dimethyl ethyl aminobenzoate | 1.0 |
| initiator | | |

Also, the non-photosensitive layer 107 may be formed using any optional material that is not photosensitive to the short-wavelength visible light such as blue light and the near-ultraviolet light, is soluble in a certain developer, and is capable of being bonded as a middle layer between the photosensitive layer 105 and the protective film layer 109. An example of such a non-photosensitive layer 107 to be used may include a binder resin obtained by removing the polymerizable monomer and the photopolymerization initiator from the components constituting the photosensitive layer 105. More specific examples thereof may include an acrylic-based resin, a methacrylic-based resin, a styrene-based resin, an epoxy-based resin, and a copolymer of an unsaturated carboxylic acid-based resin and a monoolefin-based unsaturated compound.

Also, in such a non-photosensitive layer 107, the molecular weight of the binder resin (in other words, the polymerization degree), the mixture ratio of the copolymer, or the like may be controlled to adjust the strength and the dissolution rate to a developer of the non-photosensitive layer 107.

### [Regarding Exposure Condition and Development Condition of Dry Film Photoresist]

The resist layer 103 having at least the photosensitive layer 105 and the non-photosensitive layer 107 as described above may be exposed to light using light in the range of an ultraviolet band to a visible light band on a short wavelength side (for example, a blue light band). Examples of the wavelength used for the exposure may include ultraviolet light having a wavelength of 365 nm and blue light having a wavelength of 405 nm. Furthermore, an example of the exposure condition may be, but not particularly limited to, an exposure condition of using the light having the above-described wavelength at 40 to 60 mJ/cm², and preferably at 60 mJ/cm².

The resist layer 103 exposed to light in the condition as described above may be developed using a publicly known developer. An example of such a developer may include an alkaline developer. Any publicly known alkaline developer may be used. Examples of such an alkaline developer to be used may include a 1% aqueous solution of Na₂CO₃ and a 0.268 to 2.38% solution (preferably, a 0.268% solution) of tetramethyl ammonium hydroxide (TMAH). Here, the use of TMAH as a developer enables the inhibition of the use of a Na₂CO₃ developer which adversely affects silicon, when silicon is used as a processing target material. The development condition of the exposed resist layer 103 is not particularly limited, and may be appropriately changed according to a developer used. For example, the development condition for a 1% aqueous solution of Na₂CO₃ may be appropriately 30 seconds, and that for a TMAH solution may be appropriately 40 seconds.

Also, a lift-off agent used for the resist layer 103 after the formation of a metal film is not particularly limited, and a publicly known lift-off agent such as a 2.5% solution of sodium hydroxide may be used.

In the above, the dry film photoresist according to the present embodiment has been described in detail by referring to FIG. 1.

### <Regarding Manufacturing Method of Dry Film Photoresist>

Subsequently, a manufacturing method of the dry film photoresist 10 according to the present embodiment will be briefly described by referring to FIG. 2. FIG. 2 is a flow diagram showing an example of a flow of the manufacturing method of the dry film photoresist according to the present embodiment.

In manufacturing the dry film photoresist 10 according to the present embodiment, first, a publicly known resin substrate such as polyester and polyethylene terephthalate is used as the substrate layer 101, and the photosensitive layer 105 is formed on such a substrate layer 101 (step S101). At this time, the resin containing the above-described component is used as a resin for forming the photosensitive layer 105, and the substrate layer 101 is coated with such a resin and dried to form the photosensitive layer 105.

Subsequently, the photosensitive layer 105 is coated with the resin containing the above-described component and dried to form the non-photosensitive layer 107 (step S103).

Thereafter, the non-photosensitive layer 107 is coated with resin such as polyethylene and dried to form the protective film layer 109 (step S105).

Here, the coating process and the drying process for forming each layer are not particularly limited, and publicly known processes may be utilized.

By undergoing the processes as described above, the dry film photoresist 10 according to the present embodiment may be manufactured.

In the above, the manufacturing method of the dry film photoresist according to the present embodiment has been briefly described by referring to FIG. 2.

### <Regarding Metal Pattern Forming Method>

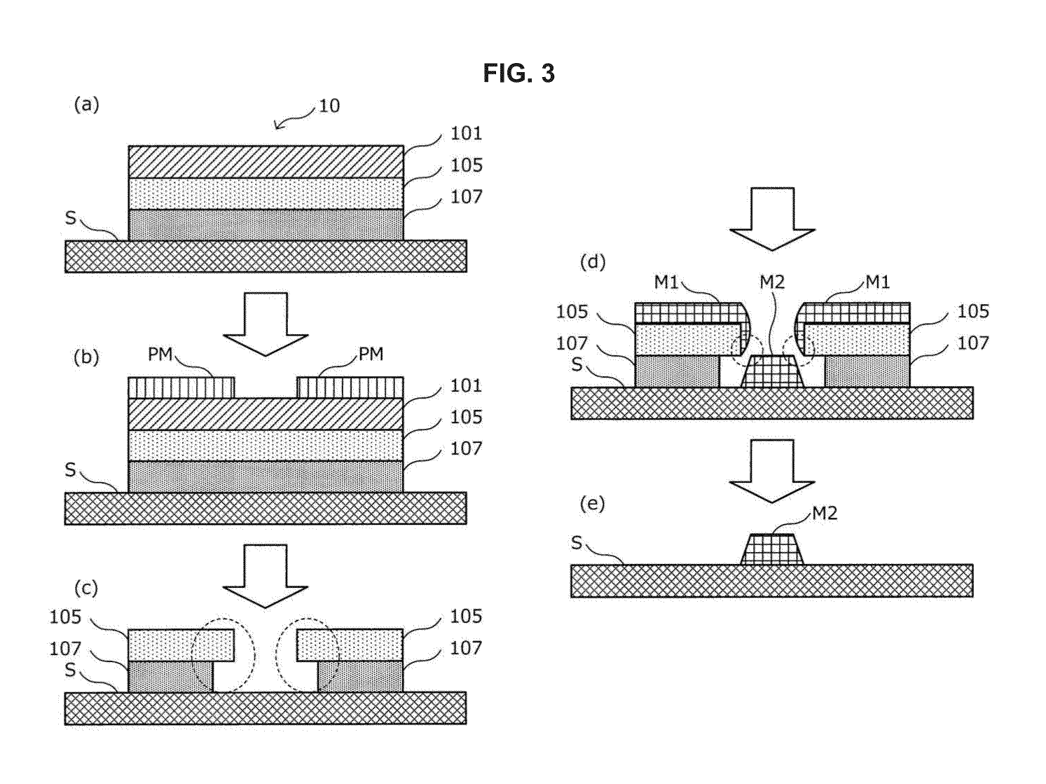

Next, a manufacturing method of a metal pattern utilizing the dry film photoresist according to the present embodiment will be briefly described by referring to FIG. 3. FIG. 3 is an illustrative diagram schematically showing a flow of the metal pattern forming method utilizing the dry film photoresist according to the present embodiment.

In the metal pattern forming method according to the present embodiment, as shown in FIG. 3(a), first, the protective film layer 109 is peeled off the dry film photoresist 10, and the dry film photoresist 10 is laminated on the surface of a processing target material S so that the non-photosensitive layer 107 abuts the surface of the processing target material S. Here, the laminating condition such as roll temperature, roll pressure and roll feeding speed is not particularly limited, and publicly known conditions may be used. By performing such laminating processing, the non-photosensitive layer 107 is positioned on the processing target material S, and the photosensitive layer 105 is positioned on the non-photosensitive layer 107.

Next, as shown in FIG. 3(b), a photo mask PM for forming a desired metal pattern is arranged on the substrate layer 101, and the dry film photoresist 10 is exposed to light in the exposure condition as described above. After the exposure, the substrate layer 101 is peeled off, and development processing is performed with, for example, an alkaline developer. Accordingly, there is formed the resist layer 103 in which a resist pattern corresponding to the pattern of the photo mask PM is formed as shown in FIG. 3(c).

Here, in the dry film photoresist 10 according to the present embodiment, the laminating order of the photosensitive layer 105 and the non-photosensitive layer 107 and the dissolution rate of the non-photosensitive layer 107 are appropriately set as previously described. This enables the formation of a so-called eaves shape in which the edge of the unexposed portion of the photosensitive layer 105 projects beyond the edge of the non-photosensitive layer 107, like the regions surrounded with dotted lines in FIG. 3(c).

Subsequently, as shown in FIG. 3(d), a metal film layer utilizing a desired metal is formed on the processing target material S on which such a resist pattern is formed, using a publicly known physical vapor deposition method such as a vapor deposition method and a sputtering method. In the dry film photoresist 10 according to the present embodiment, the dissolution rate of the non-photosensitive layer 107 may be controlled as described above to achieve a sufficient overhang amount in the eaves shape shown in FIG. 3(c). Therefore, even when the sputtering process, which causes the incident angle of metal particles to become larger, is used as a physical vapor deposition method, a metal film may be formed without the occurrence of a “burr”, thereby further reducing the limitation of the film forming method used for forming a metal film. This enables an optional metal film such as copper and platinum to be formed on the surface of the processing target material S. In the following description, for descriptive purposes, sign M1 is assigned to a metal film formed on the unexposed portion of the photosensitive layer 105, and sign M2 is assigned to a metal film formed on the surface of the processing target material S.

Next, the photosensitive layer 105 and the non-photosensitive layer 107 are lifted off together with the metal film Ml, using a publicly known lift-off agent such as a solution of sodium hydroxide. Accordingly, as shown in FIG. 3(e), a metal pattern having a desired shape may be formed through lift-off. Here, like the regions surrounded with dotted lines in FIG. 3(d), in the metal pattern forming method according to the present embodiment, discontinuity between the metal film M1 and the metal film M2 may be surely generated. As a result, in such a lift-off process, lift-off may be performed without the occurrence of a “burr”.

In the above, the metal pattern forming method according to the present embodiment has been briefly described by referring to FIG. 3.

In this manner, the dry film photoresist 10 according to the present embodiment has the photosensitive layer 105 on the side of the substrate layer 101 of the resist layer 103 and the non-photosensitive layer 107 on the side of the protective film layer 109 of the resist layer 103. Furthermore, the dissolution rate of the non-photosensitive layer 107 to a developer is higher than the dissolution rate of the unexposed portion of the photosensitive layer 105 to a developer. Accordingly, in photolithography processing, an eaves shape having a sufficient overhang amount may be more easily formed. As a result, regardless of a metal film formation method, a desired metal pattern may be accurately formed without the occurrence of a burr in one photolithography process.

Here, as in JP H11-260255A described above, a technique of forming the non-photosensitive layer on the photosensitive layer exists. However, the knowledge of appropriately controlling the dissolution rate of the non-photosensitive layer as in the dry film photoresist according to the present embodiment does not exist. Therefore, in such a technique, the eaves shape as shown in FIG. 3(c) may not be formed. Similarly, when the laminating order of the photosensitive layer and the non-photosensitive layer is different as in JP 2007-52351A described above, the eaves shape as shown in FIG. 3(c) may not be formed. Furthermore, in the metal pattern forming method according to the present embodiment, unlike JP 2007-532945A described above, a desired metal pattern may be formed in one exposure and development processing, thereby improving the productivity.

### <Regarding Manufacturing Method of Magnetic Head>

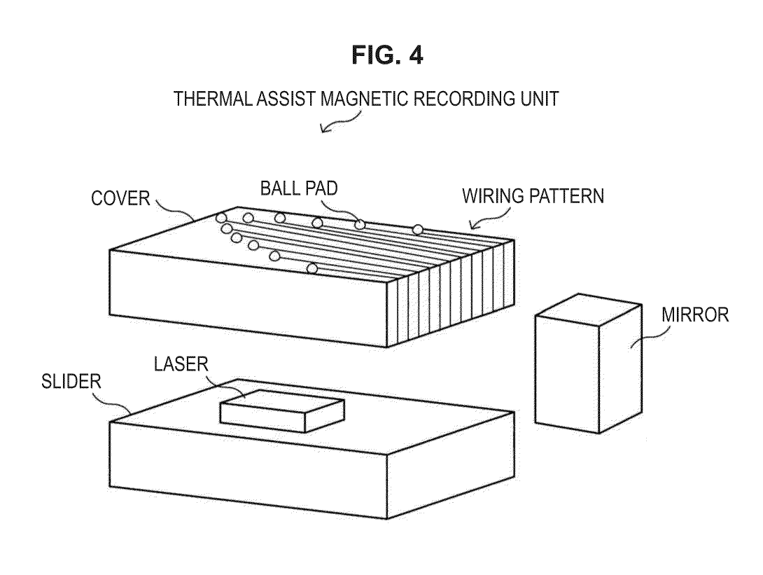

By the metal pattern forming method utilizing the dry film photoresist according to the present embodiment as described above, a publicly known electronic component manufactured through a photolithography process may be manufactured. An example of this electronic component may include a magnetic head such as a thermal assist magnetic recording unit that includes a laser, a magnetic head slider, a cover on which a wiring pattern is formed, and a mirror as shown in FIG. 4.

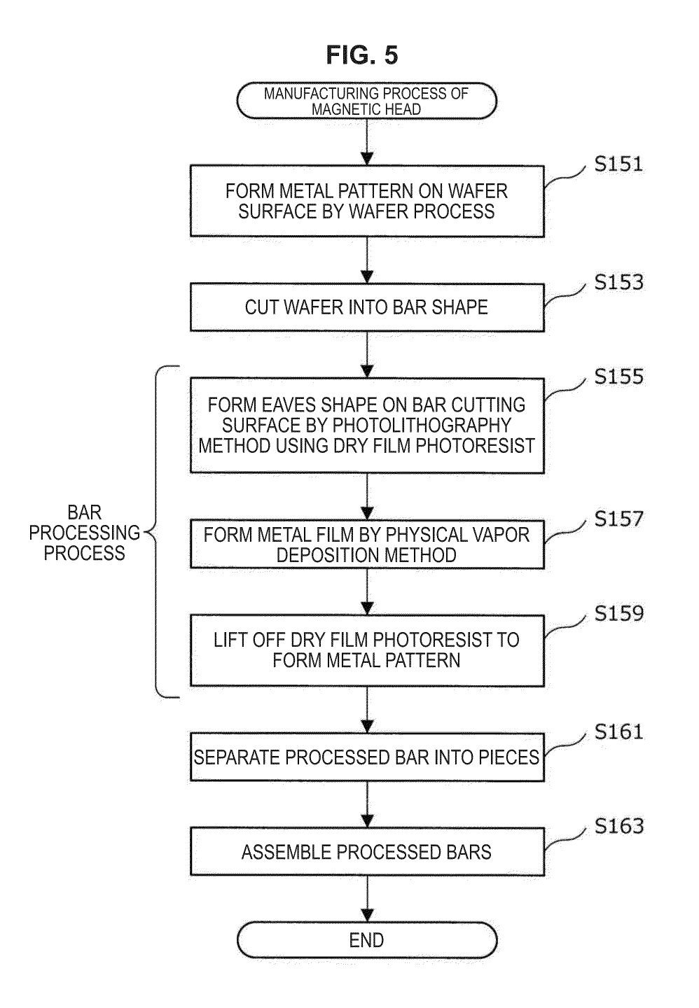

In the following, a flow of a manufacturing method of the magnetic head as shown in FIG. 4 will be briefly described by referring to FIG. 5. FIG. 5 is a flow diagram showing an example of the flow of the manufacturing method of the magnetic head according to the present embodiment.

In the manufacturing method of such a magnetic head, first, a metal pattern is formed using a desired metal on a publicly known wafer such as silicon by a publicly known wafer process (step S151). Thereafter, the wafer is cut into a bar shape (step S153), followed by a bar processing process in which each bar is processed.

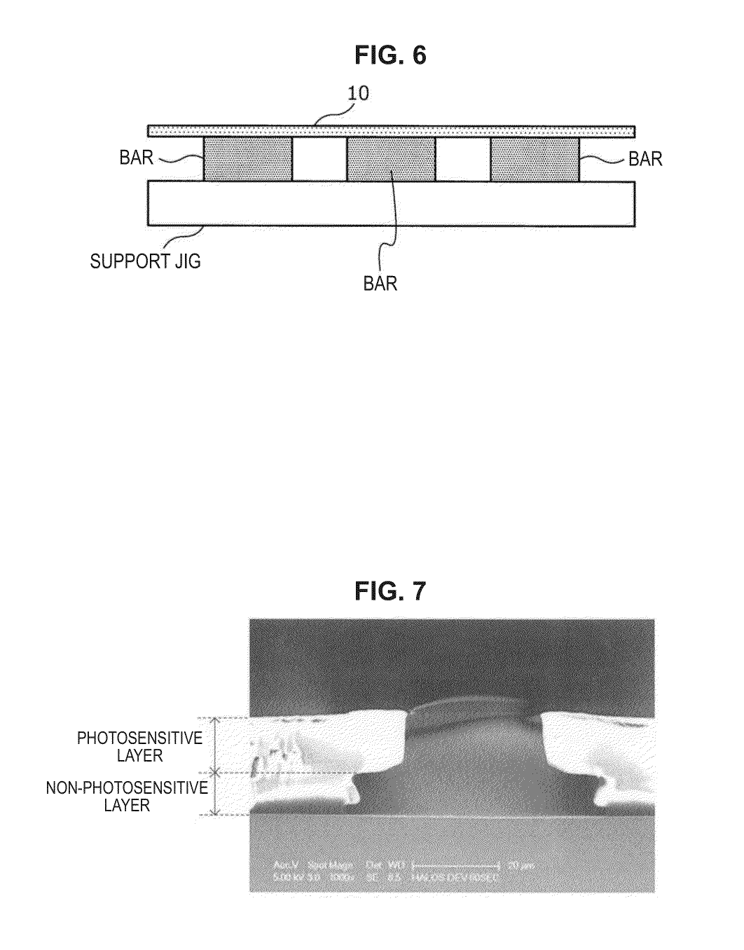

More specifically, using the dry film photoresist 10 according to the present embodiment, an eaves shape is formed to the bar cutting plane by a photolithography method (step S155). At this time, as shown in FIG. 6, the dry film photoresist 10 according to the present embodiment may be arranged on the bars arranged on a support jig to perform a photolithography method. By using the film-shaped photoresist according to the present embodiment, while the photoresist is inhibited from entering in a space between the bars and becoming non-uniform, highly accurate patterning may become possible. Also, even when the dry film photoresist 10 is arranged on the bars as shown in FIG. 6 and drops in the space between the bars to some degree, the film thickness on the bars is uniform. Accordingly, the patterning is not impaired. Thereafter, a metal film is formed by a physical vapor deposition method such as a vapor deposition method and a sputtering method (step S157). Subsequently, the dry film photoresist is lifted off to form a metal pattern (step S159).

Subsequently, the processed bars are separated into pieces (step S161), and then a slider, a laser and a cover which have been processed in a bar state are assembled (step S163). Thus, an electronic component such as a magnetic head may be manufactured.

In the above, the manufacturing method of the magnetic head according to the present embodiment has been briefly described.

### [Example]

In the following, the dry film photoresist according to an embodiment of the present disclosure will be specifically described by showing an example. It is noted that the example shown below is nothing more than an example of the dry film photoresist according to an embodiment of the present disclosure, and the dry film photoresist according to an embodiment of the present disclosure is not limited to the following example.

### [Manufacture of Dry Film Photoresist]

One surface of the substrate layer 101 constituted by a polyethylene terephthalate film with a thickness of 25 μm was coated with a photoreactive composition including the components shown in Table 1, and dried to form the photosensitive layer 105 with a thickness of 15 μm. Thereafter, such a photosensitive layer 105 was coated with the binder resin shown in Table 1, and dried to form the non-photosensitive layer 107 with a thickness of 10 μm. Subsequently, a polyethylene film with a thickness of 30 μm was laminated on such a non-photosensitive layer 107 to obtain the protective film layer 109. Thereafter, the obtained laminated film was wound into a roll shape to obtain the dry film photoresist according to an embodiment of the present disclosure.

Such a dry film photoresist satisfies the condition indicated in formula 101 above. Also, the dissolution rates of the photosensitive layer 105 and the non-photosensitive layer 107 are 1.4 [μm/ seconds] and 3.46 [μm/ seconds] respectively, which satisfy the condition indicated in formula 102 above.

### [Formation of Metal Pattern on Printed Circuit Board]

A metal pattern using platinum was formed on a publicly known printed circuit board panel, utilizing the dry film photoresist obtained in the above. More specifically, the polyethylene film that is the protective film layer 109 was peeled off the dry film photoresist 10, and the dry film photoresist 10 was laminated at a roll temperature of 80° C., a roll pressure of 3 kg/cm² and a roll feeding speed of 0.5 m/minute. Then, an unnecessary portion of the dry film photoresist was cut off. Thereafter, a film mask that becomes a mask pattern was placed on the surface of the printed circuit board panel, and irradiated with ultraviolet light (wavelength: 365 nm) at 60 mJ/cm². Thereafter, the polyethylene terephthalate film that is the substrate layer 101 was removed, and then development was performed with a 1% solution of sodium carbonate for 30 seconds, thereby to form a resist pattern having an eaves shape on the surface of the printed circuit board. A scanning electron microscope (SEM) photograph of the obtained resist pattern is shown in FIG. 7. As evident from FIG. 7, by using the dry film photoresist according to an embodiment of the present disclosure, a resist pattern having a cross-sectional eaves shape was formed by one exposure and development process.

A platinum film was formed to the dry film photoresist pattern shown in FIG. 7 utilizing a sputtering method that is one type of the physical vapor deposition method, and then the dry film resist was removed with a 2.5% aqueous solution of sodium hydroxide for metal lift-off. As a result, the metal lift-off was achieved without the occurrence of a burr to manufacture a highly accurate platinum pattern.

Here, in general, the use of a harmful drug solution such as hydrazine is involved in platinum plating. However, according to the present disclosure, the platinum pattern may be safely and accurately formed on a printed circuit board. Thus, a platinum electrode for forming an oxygen sensor, a hydrogen sensor, a hydrogen pump or the like on a printed circuit board may be safely built in.

### [Manufacture of Cover Part of Magnetic Head]

Next, utilizing the dry film photoresist obtained above, a cover part of a thermal assist magnetic recording unit as shown in FIG. 4 was manufactured.

First, a wiring pattern used for electrically connecting to a slider part was photoresist-patterned on a wafer surface of silicon, and metal is film-formed by plating, vapor deposition or a sputtering method. Then, the resist was removed to obtain a wiring pattern.

Next, the obtained wafer was cut into a bar shape, and the bar was temporarily fixed on a support jig using an adhesive material with the bar cutting surface upward. Here, the cut bars each had a size of thickness 500 μm×width 1 mm×length 25 mm, and were temporarily fixed on a support jig at a 500 μm pitch.

Subsequently, the dry film photoresist obtained above was bonded on the temporarily fixed bars, and a wiring pattern was exposed with light having a wavelength of 365 nm at 60 mJ/cm². Then, development was performed with 0.268% TMAH for 40 seconds. Thereafter, metal (aluminum) was film-formed by a vapor deposition or sputtering method. Then, the dry film photoresist was removed to form a wiring pattern on the bar cutting surface. Accordingly, the wiring pattern formed on the upper surface of the cover wafer may be electrically connected to the wiring pattern on the cutting surface. Thus, a path that connects a head gimbal with a magnetic head slider may be formed.

The cover part obtained in this manner was connected to a separately processed magnetic head slider and laser, cut into each magnetic element, and mounted with a mirror. Thus, a thermal assist magnetic recording unit was obtained.

In this manner, a resist pattern having an eaves-like resist cross-sectional shape may be obtained using the dry film photoresist according to an embodiment of the present disclosure. A metal film having an optional type, composition and layer structure may be formed to this resist pattern by a vapor deposition method or a sputtering method, and then the resist pattern is removed to lift off the metal film. Thus, an optional metal pattern, which is difficult to form by plating, may be formed without a burr.

It should be understood by those skilled in the art that various modifications, combinations, sub-combinations and alterations may occur depending on design requirements and other factors insofar as they are within the scope of the appended claims or the equivalents thereof.

Also, the effects described herein are nothing more than illustrative or exemplary, and are not limiting. That is, the technique according to the present disclosure may exert other effects that are evident from the description herein to a person skilled in the art, in addition to or in place of the above-described effects.

Additionally, the present technology may also be configured as below.

(1)
A dry film photoresist including:

a substrate layer constituted by a certain substrate;

a resist layer disposed over the substrate layer, the resist layer including a plurality of layers; and

a protective film layer disposed over the resist layer, the protective film layer protecting the resist layer,

wherein a photosensitive layer is positioned on a side of the substrate layer of the resist layer, the photosensitive layer having a dissolution rate to a certain developer that decreases by being exposed to light, and a non-photosensitive layer is positioned on a side of the protective film layer of the resist layer, the non-photosensitive layer being soluble to the developer, and

wherein a dissolution rate of the non-photosensitive layer to the developer is higher than a dissolution rate of an unexposed portion in the photosensitive layer to the developer.

(2)
The dry film photoresist according to (1),

wherein a thickness of the non-photosensitive layer is not less than 1.2 times a thickness of a metal film to be formed using the dry film photoresist.

(3)
The dry film photoresist according to (1) or (2),

wherein a thickness of the photosensitive layer is not less than twice the thickness of the metal film.

(4)
The dry film photoresist according to any one of (1) to (3),

wherein the dissolution rate of the non-photosensitive layer is a dissolution rate that allows the non-photosensitive layer to dissolve with a margin of 50% in a surplus developing time being defined as a difference between a developing time for developing the resist layer and a minimum developing time taken for developing the photosensitive layer.

(5)
The dry film photoresist according to any one of (1) to (4),

wherein the photosensitive layer is a resin layer containing at least a binder resin, a polymerizable monomer, and a photopolymerization initiator.

(6)
The dry film photoresist according to (5),

wherein the binder resin is a resin selected from the group consisting of an acrylic-based resin, a methacrylic-based resin, and an epoxy-based resin, or a copolymer of the resin, the resin or copolymer having a molecular weight of 5000 to 200000, and

wherein the polymerizable monomer is a monomer selected from the group consisting of an acrylic-based monomer, a methacrylic-based monomer, a styrene-based monomer, and an ethylene-based unsaturated compound.

(7)
The dry film photoresist according to any one of (1) to (6),

wherein the substrate is formed with polyethylene terephthalate, and

wherein the protective film layer is formed with polyethylene.

(8)
The dry film photoresist according to any one of (1) to (7),

wherein the dry film photoresist is to be developed using the developer that is alkaline.

(9)
The dry film photoresist according to any one of (1) to (8),

wherein the dry film photoresist is used for forming a metal film using a physical vapor deposition method.

(10)
A manufacturing method of a dry film photoresist, the manufacturing method including:

forming a resist layer including a plurality of layers on a certain substrate; and

forming a protective film layer that protects the resist layer on the resist layer,

wherein in forming the resist layer, a photosensitive layer is formed on a side of the substrate, the photosensitive layer having a dissolution rate to a certain developer that decreases by being exposed to light, a non-photosensitive layer is formed on a side of the protective film layer, the non-photosensitive layer being soluble to the developer, and a dissolution rate of the non-photosensitive layer to the developer is adjusted to be higher than a dissolution rate of an unexposed portion in the photosensitive layer to the developer.

(11)
A metal pattern forming method including:

arranging a dry film photoresist on a surface of a processing target material;

irradiating the dry film photoresist with exposing light, and then performing development with a certain developer, so that the dry film photoresist has a cross section of an eaves-like shape;

forming a metal film over the dry film photoresist having the processed cross section, using a physical vapor deposition method; and

removing the dry film photoresist,

wherein the dry film photoresist arranged on the surface of the processing target material has a resist layer including a plurality of layers,

wherein a non-photosensitive layer is positioned on a side of the processing target material of the resist layer, the non-photosensitive layer being soluble to the developer, and a photosensitive layer is positioned on a side of the metal film of the resist layer, the photosensitive layer having a dissolution rate to the certain developer that decreases by being exposed to light, and

wherein a dissolution rate of the non-photosensitive layer to the developer is higher than a dissolution rate of an unexposed portion in the photosensitive layer to the developer.

(12)
An electronic component manufactured using a metal pattern forming method, the metal pattern forming method including:

arranging a dry film photoresist on a surface of a processing target material;

irradiating the dry film photoresist with exposing light, and then performing development with a certain developer, so that the dry film photoresist has a cross section of an eaves-like shape;

forming a metal film over the dry film photoresist having the processed cross section, using a physical vapor deposition method; and

removing the dry film photoresist,

wherein the dry film photoresist has a resist layer including a plurality of layers,

wherein a non-photosensitive layer is positioned on a side of the processing target material of the resist layer, the non-photosensitive layer being soluble to the developer, and a photosensitive layer is positioned on a side of the metal film of the resist layer, the photosensitive layer having a dissolution rate to the certain developer that decreases by being exposed to light, and

wherein a dissolution rate of the non-photosensitive layer to the developer is higher than a dissolution rate of an unexposed portion in the photosensitive layer to the developer.

What is claimed is:

1. A dry film photoresist comprising:
a substrate layer constituted by a certain substrate;
a resist layer disposed over the substrate layer, the resist layer including a plurality of layers; and
a protective film layer disposed over the resist layer, the protective film layer protecting the resist layer,
wherein a photosensitive layer is positioned on a side of the substrate layer of the resist layer, the photosensitive layer having a dissolution rate to a certain developer that decreases by being exposed to light, and a non-photosensitive layer is positioned on a side of the protective film layer of the resist layer, the non-photosensitive layer being soluble to the developer, and
wherein a dissolution rate of the non-photosensitive layer to the developer is higher than a dissolution rate of an unexposed portion in the photosensitive layer to the developer.

2. The dry film photoresist according to claim 1,
wherein a thickness of the non-photosensitive layer is not less than 1.2 times a thickness of a metal film to be formed using the dry film photoresist.

3. The dry film photoresist according to claim 2,
wherein a thickness of the photosensitive layer is not less than twice the thickness of the metal film.

4. The dry film photoresist according to claim 1,
wherein the dissolution rate of the non-photosensitive layer is a dissolution rate that allows the non-photosensitive layer to dissolve with a margin of 50% in a surplus developing time being defined as a difference between a developing time for developing the resist layer and a minimum developing time taken for developing the photosensitive layer.

5. The dry film photoresist according to claim 1,
wherein the photosensitive layer is a resin layer containing at least a binder resin, a polymerizable monomer, and a photopolymerization initiator.

6. The dry film photoresist according to claim 5,
wherein the binder resin is a resin selected from the group consisting of an acrylic-based resin, a methacrylic-based resin, and an epoxy-based resin, or a copolymer of the resin, the resin or copolymer having a molecular weight of 5000 to 200000, and
wherein the polymerizable monomer is a monomer selected from the group consisting of an acrylic-based monomer, a methacrylic-based monomer, a styrene-based monomer, and an ethylene-based unsaturated compound.

7. The dry film photoresist according to claim 1,
wherein the substrate is formed with polyethylene terephthalate, and
wherein the protective film layer is formed with polyethylene.

8. The dry film photoresist according to claim 1,
wherein the dry film photoresist is to be developed using the developer that is alkaline.

9. The dry film photoresist according to claim 1,
wherein the dry film photoresist is used for forming a metal film using a physical vapor deposition method.

10. A manufacturing method of a dry film photoresist, the manufacturing method comprising:
forming a resist layer including a plurality of layers on a certain substrate; and
forming a protective film layer that protects the resist layer on the resist layer,
wherein in forming the resist layer, a photosensitive layer is formed on a side of the substrate, the photosensitive layer having a dissolution rate to a certain developer that decreases by being exposed to light, a non-photosensitive layer is formed on a side of the protective film layer, the non-photosensitive layer being soluble to the developer, and a dissolution rate of the non-photosensitive layer to the developer is adjusted to be higher than a dissolution rate of an unexposed portion in the photosensitive layer to the developer.

11. A metal pattern forming method comprising:
arranging a dry film photoresist on a surface of a processing target material;
irradiating the dry film photoresist with exposing light, and then performing development with a certain developer, so that the dry film photoresist has a cross section of an eaves-like shape;
forming a metal film over the dry film photoresist having the processed cross section, using a physical vapor deposition method; and
removing the dry film photoresist,
wherein the dry film photoresist arranged on the surface of the processing target material has a resist layer including a plurality of layers,
wherein a non-photosensitive layer is positioned on a side of the processing target material of the resist layer, the non-photosensitive layer being soluble to the developer, and a photosensitive layer is positioned on a side of the metal film of the resist layer, the photosensitive layer having a dissolution rate to the certain developer that decreases by being exposed to light, and
wherein a dissolution rate of the non-photosensitive layer to the developer is higher than a dissolution rate of an unexposed portion in the photosensitive layer to the developer.

12. An electronic component manufactured using a metal pattern forming method, the metal pattern forming method comprising:
arranging a dry film photoresist on a surface of a processing target material;
irradiating the dry film photoresist with exposing light, and then performing development with a certain developer, so that the dry film photoresist has a cross section of an eaves-like shape;
forming a metal film over the dry film photoresist having the processed cross section, using a physical vapor deposition method; and
removing the dry film photoresist,
wherein the dry film photoresist has a resist layer including a plurality of layers,
wherein a non-photosensitive layer is positioned on a side of the processing target material of the resist layer, the non-photosensitive layer being soluble to the developer, and a photosensitive layer is positioned on a side of the metal film of the resist layer, the photosensitive layer having a dissolution rate to the certain developer that decreases by being exposed to light, and
wherein a dissolution rate of the non-photosensitive layer to the developer is higher than a dissolution rate of an unexposed portion in the photosensitive layer to the developer.
